(19) United States
(12) Patent Application Publication
(10) Pub. No.: US 2018/0258680 A1
(43) Pub. Date: Sep. 13, 2018

(54) OPENING AND CLOSING CONTROL DEVICE

(71) Applicant: KABUSHIKI KAISHA TOKAI RIKA DENKI SEISAKUSHO, Aichi (JP)

(72) Inventor: Shuji SHITARA, Aichi (JP)

(73) Assignee: KABUSHIKI KAISHA TOKAI RIKA DENKI SEISAKUSHO, Aichi (JP)

(21) Appl. No.: 15/743,434

(22) PCT Filed: Jul. 8, 2016
(86) PCT No.: PCT/JP2016/070313

§ 371 Date: Jan. 10, 2018

(30) Foreign Application Priority Data
Jul. 22, 2015 (JP) 2015-145054

(51) Int. Cl. E05F 15/46; E05F 15/655; G01R 27/26

(52) U.S. Cl. CPC E05F 15/46; G01V 3/088; G01R 27/2605; E05F 15/655

(57) ABSTRACT

An opening/closing control device that controls movement of an opening/closing body is provided. The opening/closing control device includes a movable portion configured to move in cooperation with the movement of the opening/closing body and an entrapment detection sensor arranged on the movable portion. The entrapment detection sensor is configured to perform entrapment detection when the opening/closing body moves. The opening/closing control device further includes a control unit that moves the opening/closing body at a constant speed. The control unit is configured to execute deceleration control that changes a movement speed of the opening/closing body to a lower speed than the constant speed when the entrapment detection sensor detects a physical quantity that is less than a first threshold value and greater than or equal to a second threshold value.

### TECHNICAL FIELD

The present invention relates to an opening/closing control device that controls movement of an opening/closing body.

### BACKGROUND ART

Patent document 1 discloses a technique that arranges an electrostatic sensor on a door window, which is one example of an opening/closing body, and detects entrapment with the electrostatic sensor. When the electrostatic sensor detects entrapment as the door window closes, the movement of the door window is reversed. This releases an entrapment subject from the door window.

### PRIOR ART DOCUMENT

### Patent Document

Patent Document 1: Japanese Laid-Open Patent Publication No. 2005-314949

### SUMMARY OF THE INVENTION

### Problems that are to be Solved by the Invention

When a sensor (for example, electrostatic sensor) used to detect entrapment by a power window is set on a movable portion such as a door window, the sensor moves when detecting an entrapment subject. Thus, the sensor is susceptible to the influence of a charged object that is located nearby. This hinders the detection of the approach of a subject that should be detected.

It is an object of the present invention to provide an opening/closing control device that improves the detection accuracy of an entrapment detection sensor set on a movable portion to detect entrapment.

### Means for Solving the Problem

One aspect of the present invention is an opening/closing control device that controls movement of an opening/closing body. The opening/closing control device includes a movable portion configured to move in cooperation with the movement of the opening/closing body, and an entrapment detection sensor arranged on the movable portion. The entrapment detection sensor is configured to perform entrapment detection when the opening/closing body moves. The opening/closing control device further includes a control unit that moves the opening/closing body at a constant speed. The control unit is configured to execute deceleration control that changes a movement speed of the opening/closing body to a lower speed than the constant speed when the entrapment detection sensor detects a physical quantity that is less than a first threshold value and greater than or equal to a second threshold value.

In this structure, the movement speed of the opening/closing body is decreased to reduce the influence of a detected object located nearby and facilitate detection of an object that is subject to detection. This improves the entrapment detection accuracy of the entrapment detection sensor that is set on the movable portion.

### Effect of the Invention

The present invention improves the detection accuracy of an entrapment detection sensor set on a movable portion to detect entrapment.

### BRIEF DESCRIPTION OF THE DRAWINGS

FIG. 1 is a schematic diagram showing the configuration of a power window.

FIG. 2 is a diagram illustrating the action of a window glass moving at a low speed.

### EMBODIMENTS OF THE INVENTION

One embodiment of an opening/closing control device will now be described.

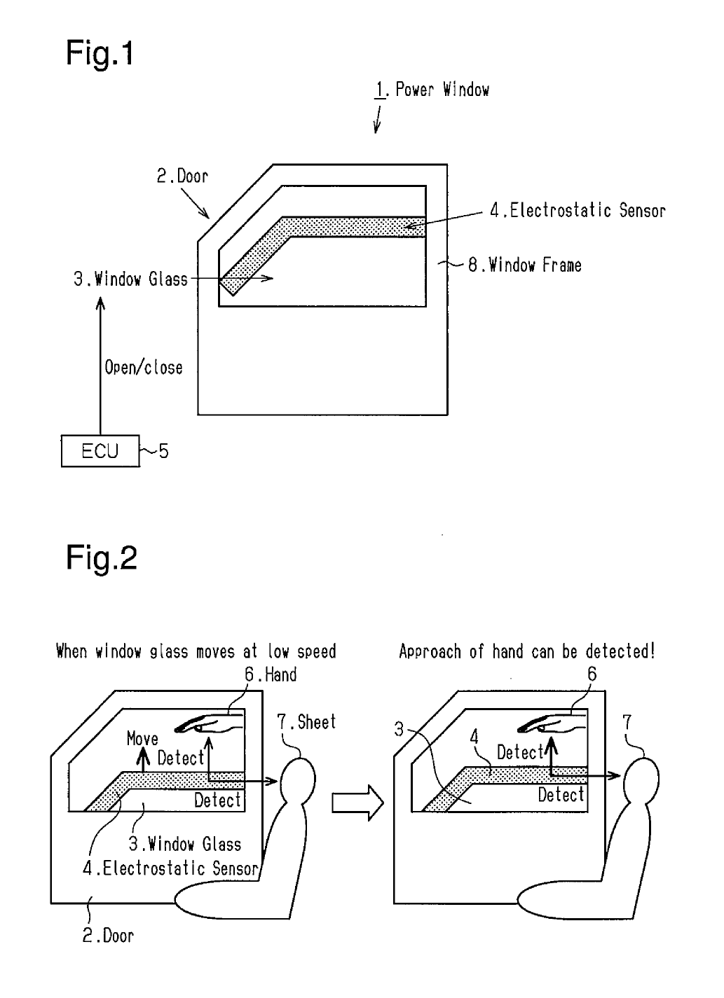

As shown in FIG. 1, a power window 1, which is one example of the opening/closing control device, controls the opening and closing movements of a window glass 3 that is arranged in a door 2 of a vehicle. The opening movement of the window glass 3 is defined by a lowering movement of the window glass 3, and the closing movement of the window glass 3 is defined by a lifting movement of the window glass 3. The window glass 3 corresponds to an opening/closing body and is a movable portion that slides in a window frame. An electrostatic sensor 4, which is one example of an entrapment detection sensor, is arranged on an upper end surface of the window glass 3 or on a side surface of the window glass 3 facing the passenger compartment proximate to an upper end. The electrostatic sensor 4 is one example of a contactless sensor and detects changes in the capacitance of a detected subject. The electrostatic sensor 4 detects entrapment when the capacitance becomes greater than or equal to a first threshold value.

The power window 1 includes an electronic control unit (ECU) 5 that centrally controls the opening and closing movements of the window glass 3 and an operation switch (not shown) that receives an operation input for starting the opening or closing movement of the window glass 3. The operation switch is arranged, for example, near a seat. When the operation switch receives an operation input, the ECU 5 centrally controls the opening and closing movements of the window glass 3 in accordance with the operation input. When a user performs an opening operation on the operation switch, the ECU 5 lowers the window glass 3 by producing an opening movement. When the user performs a closing operation on the operation switch, the ECU 5 lifts the window glass 3 by producing a closing movement.

Each of the opening operation and the closing operation includes a manual operation that stops the opening or closing movement of the window glass 3 when an operation performed by the user is cancelled and an automatic operation that continues movement of the window glass 3 until the window glass 3 reaches a fully-open position or a fully-closed position when an operation performed by the user is cancelled. The automatic operation includes an “automatic down operation” for continuing the lowering movement of the window glass 3 until the window glass 3 reaches the fully-open position and an “automatic up operation” for continuing the lifting movement of the window glass 3 until the window glass 3 reaches the fully-closed position.

When the automatic up operation is performed on the operation switch and the electrostatic sensor 4 detects entrapment, the ECU 5 reverses movement of the window glass 3. This lowers the window glass 3 and releases an entrapment subject from the window glass 3.

Further, when the automatic up operation is performed on the operation switch, the ECU 5 lifts the window glass 3 at a constant speed. In this case, when the electrostatic sensor 4 detects capacitance that is less than the first threshold value and greater than or equal to a second threshold value, the ECU 5 executes deceleration control that changes the movement speed of the window glass 3 to a lower speed than the constant speed. The movement speed during the deceleration control in the present example is a positive movement speed that is greater than zero. For example, a movement speed that is one-half or one-third of the constant speed is employed. The movement speed may be set to zero. The ECU 5 corresponds to a control means.

The operation of the power window device 1 will now be described.

As shown in the left side of FIG. 2, the automatic up operation is performed on the operation switch to lift the window glass 3 from the fully-open position at the constant speed. In this case, when a hand 6 exists between the window frame and the window glass 3, the electrostatic sensor 4 receives electric charges from both the hand 6 and a seat 7 as the window glass 3 rises. This is because the hand 6 and the seat 7 are both charged objects. The electric charges are accumulated in the electrostatic sensor 4. When the capacitance resulting from the electric charges does not reach the first threshold value in which entrapment is detected but reaches the second threshold value (for example, two-thirds of first threshold value), the deceleration control is executed on the window glass 3 to move the window glass 3 at a low speed.

The low-speed movement of the window glass 3 as shown in the right side of FIG. 2 has the following merit. A certain amount of time is required until capacitance that is greater than or equal to the first threshold value can be obtained when entrapment actually occurs. Thus, the deceleration control creates additional time. In other words, the low-speed movement of the window glass 3 provides an environment that allows electric charges to be accumulated in the electrostatic sensor 4. When the hand 6 exists between the window frame and the window glass 3, the capacitance is likely to reach the first threshold value when the hand 6 approaches the window glass 3 and before entrapment actually occurs. When the capacitance reaches the first threshold value, the movement of the window glass 3 is reversed.

As described above, the present embodiment has the following advantages.

(1) The movement speed of the window glass 3 is decreased to reduce the influence of a detected object (for example, seat 7 serving as charged object) located nearby and facilitate detection of an object that is subject to detection (for example, hand 6 serving as charged object). This improves the entrapment detection accuracy of the electrostatic sensor 4 that is set on the window glass 3, which is the movable portion.

(2) Execution of the deceleration control at a positive movement speed allows the lifting movement of the window glass 3 to be continued. The entrapment detection accuracy increases as the movement speed becomes close to zero, which is a still state.

(3) A certain amount of time is required for the capacitance to become greater than or equal to the first threshold value when entrapment actually occurs. In this regard, the deceleration control buys time. This allows for stable entrapment detection and thus improves the detection accuracy.

(4) In a configuration in which the deceleration control is executed regardless of the condition, the deceleration control is executed whenever the upper end of the window glass 3 approaches the window frame where entrapment may occur even if entrapment does not actually occur. Thus, it takes time to fully close the window glass 3. In this regard, in the present configuration, the deceleration control is executed only when the electrostatic sensor 4 detects capacitance that is greater than or equal to the second threshold value, and the deceleration control is not executed when entrapment does not actually occur and the electrostatic sensor 4 detects capacitance that is less than the second threshold value. This eliminates cases in which the window glass 3 is closed over a time that is longer than necessary.

(5) When lowering the first threshold value used to detect entrapment, the influence of a disturbance causes the capacitance to easily reach the first threshold value. Thus, the window glass 3 is likely to be erroneously reversed when the window glass 3 does not need to be reversed. In this regard, in the present configuration, the first threshold value is not lowered. This reduces erroneous reversal that would be caused by the influence of a disturbance.

The above embodiment may be modified as described below.

The movement speed during the deceleration control may be changed to any speed. Gradual deceleration control may be executed so that if the capacitance has an increasing tendency after the speed is decreased from the constant speed, the speed may be further decreased. Alternatively, gradual acceleration control may be executed if the capacitance has a decreasing tendency after the speed is decreased from the constant speed to return the speed to the constant speed.

In this case, a method for monitoring a pulse in accordance with a rotation speed of a motor, which serves as a drive source, a method for monitoring a current value of the motor, a method for monitoring a signal of a fully-closed switch, or the like may be used as a method for detecting the position of the window glass 3.

The present invention may be applied to an opening/closing control device that controls an opening/closing body such as a shutter of a building in which an opening movement is defined by a lifting operation and a closing movement is defined by a lowering operation.

The present invention may be applied to an opening/closing control device that controls an opening/closing body that moves in the horizontal direction, for example, a sliding door of a vehicle or an automatic door of a building.

The present invention may be applied to an opening/closing control device that controls a sunroof or the like of a vehicle.

The power window 1 according to the embodiment may be employed as an example of an entrapment detection device that sets an entrapment detection sensor on a movable portion that moves in cooperation with the opening/closing body and performs entrapment detection using the entrapment detection sensor when the opening/closing body moves. In this case, the power window 1 includes a control means that monitors entrapment detection with the entrapment detection sensor while executing the deceleration control that decreases the movement speed of the opening/closing body from the constant speed if the entrapment detection sensor detects a physical quantity that is greater than or equal to the second threshold value when the opening/closing body moves at the constant speed. The ECU 5 according to the embodiment corresponds to the control means.

1. An opening/closing control device that controls movement of an opening/closing body, the opening/closing control device comprising:
a movable portion configured to move in cooperation with the movement of the opening/closing body;
an entrapment detection sensor arranged on the movable portion, wherein the entrapment detection sensor is configured to perform entrapment detection when the opening/closing body moves; and
a control unit that moves the opening/closing body at a constant speed, wherein the control unit is configured to execute deceleration control that changes a movement speed of the opening/closing body to a lower speed than the constant speed when the entrapment detection sensor detects a physical quantity that is less than a first threshold value and greater than or equal to a second threshold value.

2. The opening/closing control device according to claim 1, wherein the control unit executes the deceleration control at a positive movement speed that is greater than zero.

3. The opening/closing control device according to claim 1, wherein
the entrapment detection sensor is an electrostatic sensor that detects capacitance, which is electric charge accumulated in a detection subject, as the physical quantity, and
the entrapment detection sensor detects entrapment when the capacitance becomes greater than or equal to the first threshold value.

4. The opening/closing control device according to claim 1, wherein
the opening/closing body includes a window frame and a window glass that slides in the window frame, and
the movable portion is the window glass.

5. The opening/closing control device according to claim 1, wherein
the control unit monitors entrapment detection with the entrapment detection sensor when moving the opening/closing body at the constant speed and when executing the deceleration control on the opening/closing body.
